(19) United States
(12) Patent Application Publication
(10) Pub. No.: US 2005/0176191 A1
(43) Pub. Date: Aug. 11, 2005

(54) Method for fabricating a notched gate structure of a field effect transistor

(75) Inventors: Ajay Kumar, Sunnyvale, CA (US); Padmapani C. Nallan, San Jose, CA (US)

Correspondence Address: Patent Counsel;Applied Materials, Inc., P.O. Box 450A, Santa Clara, CA, 95052, US

(73) Assignee: Applied Materials, Inc.

(21) Appl. No.: 10/358,970

(22) Filed: Feb. 4, 2003

(51) Int. Cl. H01L 21/336; H01L 21/8234; H01L 21/8242; H01L 21/3205; H01L 21/4763; H01L 21/44

(52) U.S. Cl. 438/197; 438/585; 438/666

(57) ABSTRACT

A method of fabricating a gate structure of a field effect transistor comprising a gate dielectric that is notched beneath a gate electrode using an isotropic plasma etch process. In one embodiment, the etch process uses a gas comprising a halogen gas (e.g., chlorine (Cl₂)), a hydrocarbon gas (e.g., methane (CH₄)), and an optional reducing gas (e.g., carbon monoxide (CO)), applies a substrate bias of not greater than 20 W, and maintains the substrate temperature of not less than 200 degrees Celsius.

### BACKGROUND OF THE INVENTION

1. Field of Invention

The present invention generally relates to a method for fabricating devices on semiconductor substrates. More specifically, the present invention relates to a method for fabricating a field effect transistor.

2. Description of the Background Art

Ultra-large-scale integrated (ULSI) circuits typically include more than one million transistors that are formed on a semiconductor substrate and cooperate to perform various functions within an electronic device. Such transistors generally are complementary metal-oxide-semiconductor (CMOS) field effect transistors.

A CMOS transistor has a gate structure disposed between a source region and a drain region formed in the semiconductor substrate. The gate structure generally comprises a gate electrode and gate dielectric. The gate electrode is provided over the gate dielectric and controls a flow of charge carriers in a channel region that is formed between the drain and source regions beneath the gate dielectric to turn the transistor on or off. The channel, drain, and source regions are collectively referred to in the art as a “transistor junction”. There is a constant trend to reduce topographic dimensions of the gate dielectric and, as such, decrease the length of the channel region to thereby increase the operational speed of the transistor.

An advanced CMOS transistor generally utilizes a polysilicon gate electrode and the gate dielectric fabricated of very thin (e.g., 20 to 60 Angstroms) layers of HfO₂, HfSiO₂, HfSiON, Al₂O₃, ZrO₂, barium strontium titanate (BST), lead zirconate titanate (PZT), ZrSiO₂, TaO₂, and the like. Such dielectric materials have a dielectric constant that is greater than 4.0 and are referred to in the art as high-K materials.

In the prior art, to fabricate a CMOS transistor, regions in the substrate are doped using, e.g., an ion implantation process, to form the source and drain regions. Further, a high-K dielectric layer and a polysilicon layer are sequentially deposited on the substrate and then a patterned etch mask (e.g., silicon dioxide (SiO₂ mask) is formed upon the polysilicon layer. Portions of the high-K dielectric and polysilicon layers that are not protected by the mask are selectively removed using an etch process. The remaining protected portions of the layers form, respectively, a gate dielectric and gate electrode having, as well as the etch mask, the same topographic dimensions. As such, in the prior art, the length of the channel region in the transistor junction cannot be reduced more than to about a width of the gate electrode or mask.

Therefore, there is a need in the art for a method of fabricating a gate structure of a field effect transistor comprising a high-K gate dielectric that has smaller topographic dimensions than the gate electrode.

### SUMMARY OF INVENTION

A method of fabricating a gate structure of a field effect transistor comprising an isotropic plasma etch process that forms a notched gate dielectric beneath the gate electrode of the structure. In one embodiment, the isotropic plasma etch process provides a gas comprising a halogen gas (e.g., chlorine (Cl₂)), a hydrocarbon gas (e.g., methane (CH₄)), and an optional reducing gas, such as carbon monoxide (CO), as well as applies a substrate bias of not greater than about 20 W and maintains the substrate temperature of not less than about 200 degrees Celsius.

In one application, the method is used to fabricate the gate structure having notched polysilicon gate electrode and ultra-thin (e.g., about 20 to 60 Angstroms) notched gate dielectric that is formed from a material having a dielectric constant greater than 4.0, such as HfO₂, HfSiO₂, HfSiON, Al₂O₃, ZrO₂, barium strontium titanate (BST), lead zirconate titanate (PZT), ZrSiO₂, TaO₂, and the like.

### BRIEF DESCRIPTION OF DRAWINGS

The teachings of the present invention can be readily understood by considering the following detailed description in conjunction with the accompanying drawings, in which:

FIG. 1 depicts a flow diagram of a method of fabricating a gate structure of a field effect transistor in accordance with the present invention;

FIGS. 2A-2F, together, depict a sequence of schematic, cross-sectional views of a substrate having a gate structure being formed in accordance with the method of FIG. 1;

FIG. 3 depicts a schematic diagram of an exemplary plasma processing apparatus of the kind used in performing portions of the inventive method; and

FIG. 4 is a table summarizing the processing parameters of one embodiment of the inventive method when practiced using the apparatus of FIG. 3.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of fabricating a gate structure of a field effect transistor (e.g., a complementary metal-oxide-semiconductor (CMOS) field effect transistor). In one embodiment, a gate electrode and gate dielectric of the structure are selectively notched using an isotropic plasma etch (IPE) process that partially removes a high-K gate dielectric layer between the gate electrode and semiconductor substrate.

The invention is generally used for fabricating gate structures comprising ultra-thin (e.g., about 20 to 60 Angstroms) notched gate dielectrics formed from at least one film of a dielectric material having the dielectric constant greater than 4.0 (i.e., high-K dielectric materials). Such dielectric materials comprise hafnium dioxide (HfO₂), HfSiO₂, HfSiON, Al₂O₃, ZrO₂, barium strontium titanate (BST), lead zirconate titanate (PZT), ZrSiO₂, TaO₂, and the like.

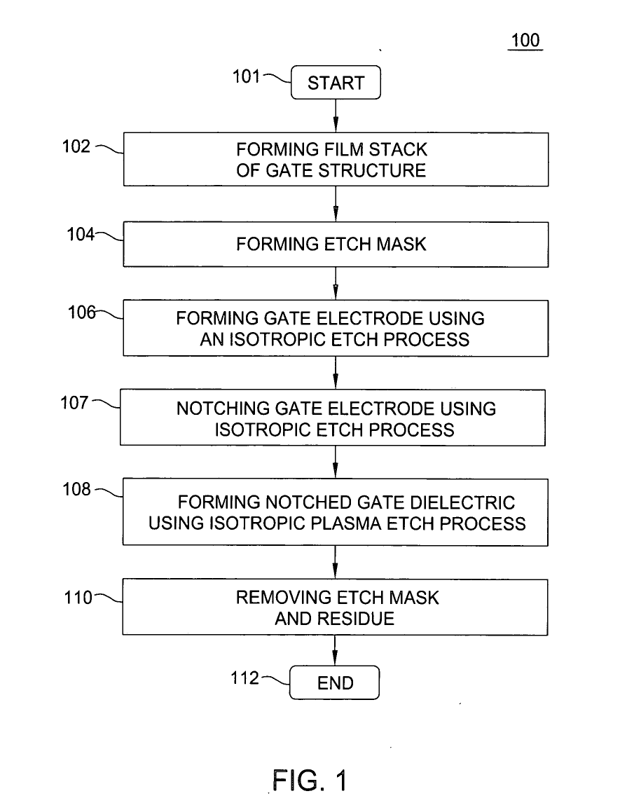

FIG. 1 depicts a flow diagram of a method 100 of fabricating a gate structure in accordance with the present invention. The method 100 comprises processes that are performed upon a film stack of the gate structure during fabrication of a field effect transistor (e.g., CMOS transistor) having a notched gate dielectric.

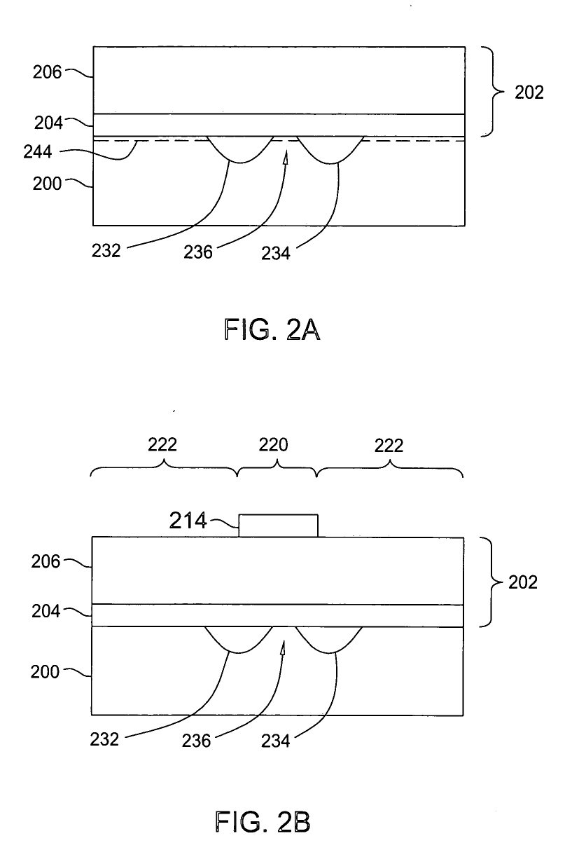

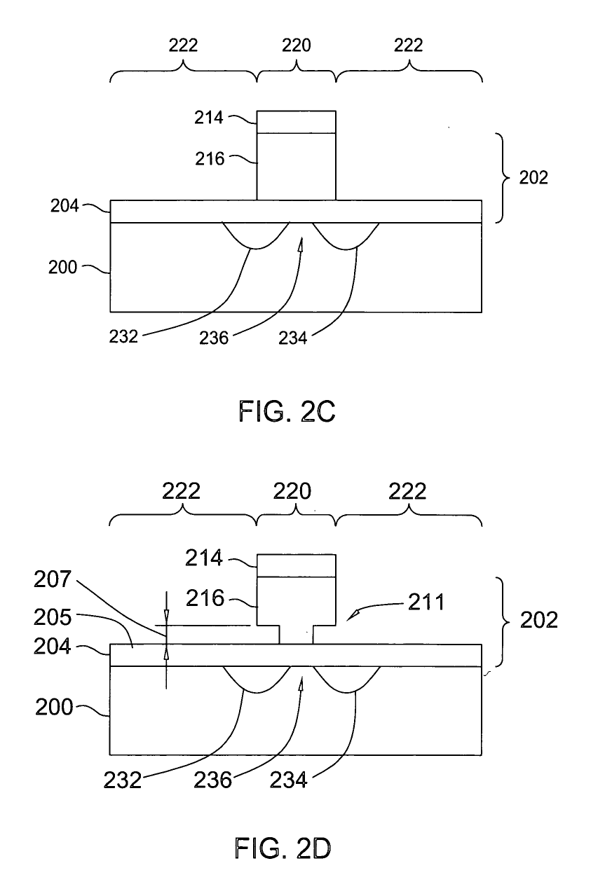

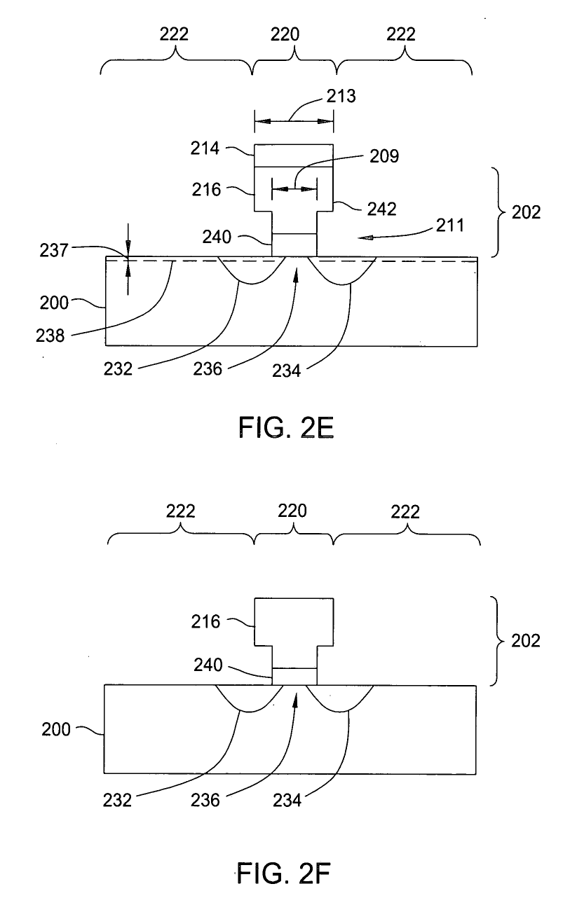

FIGS. 2A-2F, together, depict a sequence of schematic, cross-sectional views of a substrate having a gate structure being formed in accordance with the method 100 of FIG. 1. The cross-sectional views in FIGS. 2A-2F relate to individual processing steps that are used to form the gate structure. Conventional sub-processes (e.g., exposure and development of photoresist, wafer cleaning procedures, and the like) are well known in the art and, as such, are not shown in FIG. 1 and FIGS. 2A-2F. The images in FIGS. 2A-2F are not depicted to scale and are simplified for illustrative purposes.

The method 100 starts at step 101 and proceeds to step 102, when a film stack 202 is formed on a wafer 200 (FIG. 2A). The wafer 200, e.g., a silicon (Si) wafer, comprises doped source and drain regions (wells) 232 and 234 that are separated by a channel region 236 of the transistor. In an alternative embodiment, the wafer 200 may further comprise a spacer film 244 (shown in broken line in FIG. 2A only) protecting the channel region 236 from diffusive contaminants (e.g., oxygen (O₂) and the like) that may be contained in a gate dielectric layer 204. The spacer film is generally formed from silicon dioxide (SiO₂), silicon nitride (Si₃N₄), and the like.

The film stack 202 comprises an electrode layer 206 and the high-K dielectric layer 204. In one illustrative embodiment, the electrode layer 206 is formed from doped polysilicon (Si) to a thickness of about 500 to 6000 Angstroms, and the dielectric layer 204 is formed from hafnium dioxide (HfO₂) to a thickness of about 20 to 60 Angstroms. In alternative embodiment, the layer 204 may comprise at least one film of a high-K material other than hafnium dioxide (e.g., HfSiO₂, A₂O₃, and the like) or be formed to a different thickness. The layers 204 and 206 may be provided using a vacuum deposition technique, such as an atomic layer deposition (ALD), a chemical vapor deposition (CVD), plasma enhanced CVD (PECVD), and the like.

At step 104, a patterned mask 214 is formed on the electrode layer 206 in the region 220 (FIG. 2B). The mask 214 defines location and topographic dimensions of a gate electrode of the gate structure being formed using the method 100. Further, the mask 214 protects the channel region 236 and portions of the source and drain regions 232 and 234 in the region 220, while exposing the adjacent regions 222 of the wafer 200. For illustrative purposes, views in FIGS. 2B-2F depict only portions of the mask 214 and regions 222 that are disposed near the gate structure. The mask 214 is generally a hard mask formed from a material that is stable at the wafer temperatures up to 500 degrees Celsius. Such wafer temperatures may be used during the IPE process (discussed in reference to step 108 below). The mask materials comprise high-K dielectric materials, silicon dioxide, Advanced Patterning Film™ (APF) available from Applied Materials, Inc. of Santa Clara, and the like. In one illustrative embodiment, the mask 214 is formed from APF. Processes for applying such masks are described, e.g., in commonly assigned U.S. patent application Ser. No. 10/245,130, filed Sep. 16, 2002 (Attorney docket number 7524) and Ser. No. 09/590,322, filed Jun. 8, 2000 (Attorney docket number 4227), which are incorporated herein by reference.

At step 106, the electrode layer 206 is etched and removed in the regions 222 (FIG. 2C). A remaining portion of the layer 206 forms in the region 220 a gate electrode 216 (e.g., polysilicon gate electrode). Step 106 uses the mask 214 as an etch mask and may use the dielectric layer 204 (e.g., hafnium dioxide layer) as an etch stop layer. In one illustrative embodiment, step 106 performs an anisotropic plasma etch process using a gas (or gas mixture) comprising at least one of chlorine (Cl₂), hydrogen bromide (HBr), carbon tetrafluoride (CF₄), and the like. Herein the terms “gas” and “gas mixture” are used interchangeably. The anisotropic plasma etch process provides selectivity to polysilicon over a high-K dielectric material (e.g., HfO₂, HfSiO₂, and the like) of about 100:1, as well as selectivity to polysilicon over the silicon dioxide or APF mask of about (5-6):1. Such anisotropic plasma etch process is disclosed in commonly assigned U.S. patent application Ser. No. 10/194,609, filed Jul. 12, 2002 (Attorney docket number 7365), which is incorporated herein by reference.

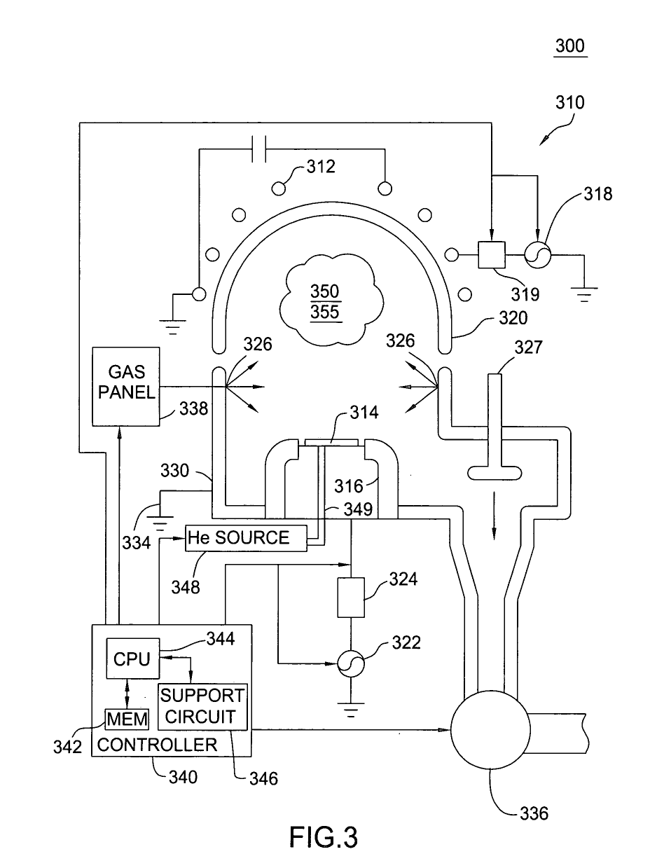

Step 106 can be performed, for example, using a Decoupled Plasma Source (DPS) reactor of the CENTURA® semiconductor wafer processing system available from Applied Materials, Inc. of Santa Clara, Calif. The DPS reactor uses an inductive source to produce a high-density plasma and comprises a source of radio-frequency (RF) power to bias the wafer. The DPS reactor is described in more detail in reference to FIG. 3 below.

In one embodiment, using the DPS reactor, step 106 provides hydrogen bromide at a rate of 20 to 300 sccm and chlorine at a rate of 20 to 300 sccm (i.e., a HBr:Cl₂ flow ratio ranging from 1:15 to 15:1), as well as nitrogen (N₂) at a rate of 0 to 200 sccm. Further, step 106 applies 200 to 3000 W of plasma power and 0 to 300 W of bias power and maintains a wafer temperature at 0 to 200 degrees Celsius and a pressure in the reaction chamber at 2 to 100 mTorr. One exemplary process provides HBr at a rate of 40 sccm and Cl₂ at a rate of 40 sccm (i.e., a HBr:Cl₂ flow ratio of about 1:1), N₂ at a rate of 20 sccm, 1100 W of plasma power, 20 W of bias power, a wafer temperature of 45 degrees Celsius, and a pressure of 4 mTorr.

At step 107, the gate electrode 216 is notched in a corner region 211 to a pre-determined width 209 using a lateral etch process (FIG. 2D). Generally, a height 207 of a notch is about 500 Angstroms. In one embodiment, step 107 deposits on the mask 214 and sidewalls 242 of the gate electrode 216 a protective polymeric coating that thins towards the corner region 211. Further, step 107 laterally etches the gate electrode 216 to form the notch using a plasma comprising sulfur hexafluoride (SF₆) and then strips the protective coating. The polymeric coating may be formed using a passivating gas that comprises at least one fluorocarbon or hydrofluorocarbon gas, such as C₄F₈, trifluoromethane (CHF₃), and the like. In an alternative embodiment, when the sidewalls 242 are protected using a spacer film (e.g. film of silicon dioxide, silicon nitride (Si₃N₄), and the like), the lateral etch process may use a gas comprising hydrogen bromide (HBr), carbon tetrafluoride (CF₄), chlorine (Cl₂), and the like. Such etch processes are disclosed in commonly assigned U.S. patent application Ser. No. 10/273,802, filed Oct. 17, 2002 and Ser. No. 10/194,609, filed Jul. 12, 2002, which are incorporated herein by reference.

At step 108, the high-K dielectric layer 204 is removed in an open area (regions 222) and between the notched gate electrode 216 and the wafer 200 using the IPE process that forms a notched gate electrode 240 (FIGS. 2D, 2E). The notched gate dielectric 240 is disposed between the gate electrode 216 and wafer 200 above the channel region 236 and adjacent portions of the wells 232 and 234. In one embodiment, the IPE process continues until the notched gate dielectric 240 is formed to the width 209, as depicted in FIG. 2E. The width 209 may be substantially less than a width 213 of the mask 214 and gate electrode 216. In another embodiment (not shown), the IPE process continues until the notched gate electrode 240 is formed to a width that is smaller than the width 209. As such, in either embodiment, the IPE process may be used to fabricate a field effect transistor (e.g., a CMOS transistor) comprising the channel region 336 having a length that is smaller than the width 213.

In one embodiment, the IPE process uses a gas comprising a halogen gas such as chlorine and the like, a hydrocarbon gas such as methane (CH₄), ethylene (C₂H₆), propane (C₃H₈), butane (C₄H₁₀), and the like, as well as an optional reducing gas, such as carbon monoxide (CO). Further, the IPE process applies a substrate bias of not greater than 20 W and maintains the wafer 200 at the temperature of not less than 200 degrees Celsius.

The type of a halogen gas (e.g., chlorine) is selected to best remove atoms of metal from the high-K dielectric layer 204 (e.g., layer of HfO₂, HfSiO₂, and the like), and the hydrocarbon gas (e.g., methane) is selected to increase the etch selectivity to the layer over polysilicon and silicon. Further, the type of a reducing gas is selected to best remove the oxygen from the layer 204. Step 108 provides high etch selectivity to the high-K dielectric material of the gate dielectric layer 204 over polysilicon (gate electrode 216), silicon (wafer 200), and APF or silicon dioxide (mask 214).

Since step 108 applies no substrate bias or applies a deliberately low bias (e.g., not greater than about 20 W at about 50 kHz to 13.56 MHz), the step etches the dielectric layer 204 only chemically or substantially only chemically. As such, step 108 etches the layer isotropically (i.e., does not sputter the layer 204) in contrast to a conventional plasma etch process that applies the substrate bias greater than 20 W (e.g., between 50 and 100 W) and etches the dielectric layer 204 both chemically and physically (i.e., sputters the layer 204).

A chemical nature of step 108 facilitates high selectivity of the IPE process to the dielectric material of the layer 204 over silicon polysilicon, silicon, and materials of the mask 214. In general terms, step 108 performs a plasma enhanced chemical etch process. Such a process etches and removes the dielectric layer 204 (e.g., layer of hafnium dioxide and the like) in the regions 222, as well notches the layer 204 under the gate electrode 216, i.e., between the notched gate electrode 216 and the wafer 200.

Step 108 contemporaneously etches a frontal surface 205 of the dielectric layer 204 in the regions 222 and in a region under the notched gate electrode 216. However, in some embodiments, a portion of the high-K gate dielectric layer 204 may remain in the corner region 211 after the layer has been removed in the regions 222. In such embodiments, the IPE process continues etching the dielectric layer 204 until the notched gate dielectric 240 is formed and, as such, the process may form shallow recesses 238 (shown in phantom in FIG. 2E). The recesses 238 have a depth 237 of a few Angstroms only due to high selectivity of the IPE process to silicon, as discussed above. Similarly, during step 108, losses of material on the sidewalls 242 also do not exceed a few Angstroms only due to high selectivity of the IPE process to polysilicon. In an alternative embodiment (not shown), step 107 may be skipped, while the high-K gate dielectric layer 204 is notched using the IPE process, as described above.

In one embodiment, using the DPS reactor to etch the dielectric layer 204, step 108 provides chlorine at a rate of 5 to 300 sccm and methane at a rate of 2 to 200 sccm (i.e., a Cl₂:CH₄ flow ratio ranging from 1:40 to 150:1), as well as carbon monoxide at a rate of 5 to 300 sccm, corresponding to a Cl₂:CO flow ratio ranging from 1:60 to 60:1 and CH₄:CO flow ratio ranging from 1:150 to 40:1. Further, step 108 applies 200 to 3000 W of plasma power and a bias power of not greater than about 20 W, and maintains a wafer temperature of not less than about 200 degrees Celsius and a pressure in the reaction chamber at 2 to 100 mTorr.

During etching the HfO₂ layer 204, one exemplary process provides Cl₂ at a rate of 20 sccm, CH₄ at a rate of 10 sccm, and CO at a rate of 20 sccm (i.e., Cl₂:CH₄, Cl₂:CO, and CH₄:CO flow ratios of about 2:1, 1:1, and 1:2, correspondingly), as well as argon (Ar) at a rate of 40 sccm, 300 W of plasma power, 20 W of bias power, a wafer temperature of 350 degrees Celsius, and a pressure of 4 mTorr. Such process etches HfO₂ at a rate of about 120 Angstroms/min and provides selectivity to hafnium dioxide over silicon (wafer 200) and polysilicon (gate electrode 216) greater than 5:1 and over APF and silicon dioxide (mask 214) greater than 10:1 and 5:1, respectively.

During etching the HfSiO₂ layer 204, another exemplary process provides Cl₂ at a rate of 20 sccm, CH₄ at a rate of 10 sccm, and CO at a rate of 20 sccm (i.e., Cl₂:CH₄, Cl₂:CO, and CH₄:CO flow ratios of about 2:1, 1:1, and 1:2, correspondingly), as well as argon (Ar) at a rate of 40 sccm, 300 W of plasma power, 20 W of bias power, a wafer temperature of 350 degrees Celsius, and a pressure of 4 mTorr. Such process etches HfSiO₂ at a rate of about 100 Angstroms/min and provides selectivity to hafnium silicate over silicon and polysilicon greater than 3:1 and over APF and silicon dioxide (mask 214) greater than 10:1 and 2:1, respectively.

At step 110, the mask 214 is removed from the gate electrode 216 using, e.g., a plasma stripping process (FIG. 2F). In an optional embodiment, remaining post-strip residue may further be removed using a residue cleaning process. Applicable stripping and residue cleaning processes are disclosed, e.g., in commonly assigned U.S. patent application Ser. No. 10/245,130, filed Sep. 16, 2002 and Ser. No. 10/338,251, filed Jan. 6, 2003, which are incorporated herein by reference. At step 112, the method 100 ends.

FIG. 3 depicts a schematic diagram of an exemplary Decoupled Plasma Source (DPS) etch reactor 300 that may be used to practice portions of the invention. The DPS reactor is available from Applied Materials, Inc. of Santa Clara, Calif.

The reactor 300 comprises a process chamber 310 having a wafer support pedestal 316 within a conductive body (wall) 330, and a controller 340.

The support pedestal (cathode) 316 is coupled, through a first matching network 324, to a biasing power source 322. The biasing source 322 generally is a source of up to 500 W at a frequency of approximately 13.56 MHz that is capable of producing either continuous or pulsed power. In other embodiments, the source 322 may be a DC or pulsed DC source. The chamber 310 is supplied with a dome-shaped dielectric ceiling 320. Other modifications of the chamber 310 may have other types of ceilings, e.g., a substantially flat ceiling. Above the ceiling 320 is disposed an inductive coil antenna 312. The antenna 312 is coupled, through a second matching network 319, to a plasma power source 318. The plasma source 318 typically is capable of producing up to 3000 W at a tunable frequency in a range from 50 kHz to 13.56 MHz. Typically, the wall 330 is coupled to an electrical ground 334.

A controller 340 comprises a central processing unit (CPU) 344, a memory 342, and support circuits 346 for the CPU 344 and facilitates control of the components of the DPS etch process chamber 310 and, as such, of the etch process, as discussed below in further detail.

In operation, a semiconductor wafer 314 is placed on the pedestal 316 and process gases are supplied from a gas panel 338 through entry ports 326 and form a gaseous mixture 350. The gaseous mixture 350 is ignited into a plasma 355 in the chamber 310 by applying power from the plasma and bias sources 318 and 322 to the antenna 312 and the cathode 316, respectively. The pressure within the interior of the chamber 310 is controlled using a throttle valve 327 and a vacuum pump 336. The temperature of the chamber wall 330 is controlled using liquid-containing conduits (not shown) that run through the wall 330.

The temperature of the wafer 314 is controlled by stabilizing a temperature of the support pedestal 316. In one embodiment, the helium gas from a gas source 348 is provided via a gas conduit 349 to channels formed by the back of the wafer 314 and grooves (not shown) in the pedestal surface. The helium gas is used to facilitate heat transfer between the pedestal 316 and the wafer 314. During the processing, the pedestal 316 may be heated by a resistive heater (not shown) within the pedestal to a steady state temperature and then the helium gas facilitates uniform heating of the wafer 314. Using such thermal control, the wafer 314 is maintained at a temperature of between 0 and 500 degrees Celsius.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the process chamber 310 as described above, the controller 340 may be one of any form of general-purpose computer processor that can be used in an industrial setting for controlling various chambers and sub-processors. The memory, or computer-readable medium, 342 of the CPU 344 may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like. The inventive method is generally stored in the memory 342 as software routine. The software routine may also be stored and/or executed by a second CPU (not shown) that is remotely located from the hardware being controlled by the CPU 344.

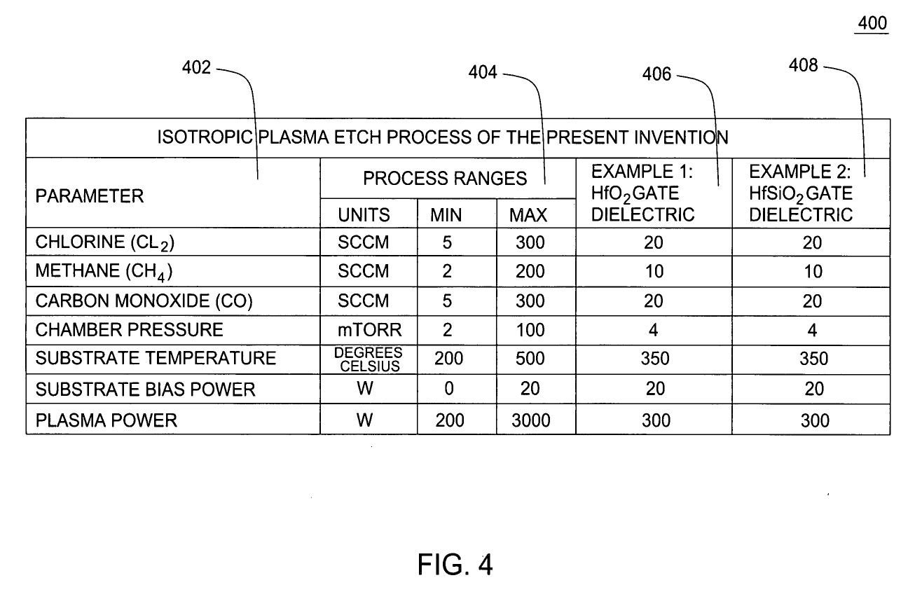

FIG. 4 presents a table 400 summarizing the process parameters of the IPE process through which one can practice the invention using the exemplary DPS etch reactor. The process parameters for one embodiment of the invention presented above are summarized in column 402. The process ranges are presented in column 404. Exemplary process parameters for etching the gate dielectric layer 204 formed from HfO₂ and HfSiO₂ during step 108 of the method 100 are presented in columns 406 and 408, respectively. It should be understood, however, that the use of different plasma etch reactor may necessitate different process parameter values and ranges.

The invention may be practiced using other semiconductor wafer processing systems wherein the processing parameters may be adjusted to achieve acceptable characteristics by those skilled in the arts by utilizing the teachings disclosed herein without departing from the spirit of the invention.

Although the forgoing discussion referred to fabrication of the field effect transistor, fabrication of the other devices and structures used in the integrated circuits can benefit from the invention.

While foregoing is directed to the illustrative embodiment of the present invention, other and further embodiments of the invention may be devised without departing from the basic scope thereof, and the scope thereof is determined by the claims that follow.

1. A method of fabricating a gate structure of a transistor, comprising:
supplying a substrate comprising a gate dielectric layer and a gate electrode layer, where the gate dielectric layer is fabricated of a material having a dielectric constant greater than 4.0;
forming a gate electrode above a channel region and portions of source and drain regions of the transistor; and
isotropically etching the gate dielectric layer to notch the gate dielectric layer beneath the gate electrode using a plasma formed from a halogen containing gas and a hydrocarbon gas.

2. The method of claim 1 wherein the forming step further comprises isotropically etching the gate electrode to notch the gate electrode above the gate dielectric layer.

3. The method of claim 1 wherein the gate dielectric layer comprises at least one of HfO₂, HfSiO₂, HfSiON, Al₂O₃, ZrO₂, barium strontium titanate (BST), lead zirconate titanate (PZT), ZrSiO₂, and TaO₂.

4. The method of claim 1 wherein the gate dielectric layer has a thickness about 20 to 60 Angstroms.

5. The method of claim 1 wherein the isotropically etching step further comprises applying a substrate bias power of not greater than about 20 W.

6. The method of claim 5 wherein the isotropically etching step further comprises applying no substrate bias power.

7. The method of claim 1 wherein the isotropically etching step further comprises maintaining the substrate at the temperature of not less than about 200 degrees Celsius.

8. (canceled)

9. The method of claim 1 wherein the plasma further comprises a reducing gas.

10. The method of claim 1 wherein the halogen containing gas comprises a chlorine containing gas.

11. The method of claim 10 wherein the chlorine containing gas is Cl₂.

12. The method of claim 1 wherein the hydrocarbon gas comprises at least one of CH₄, C₂H₆, C₃H₈, and C₄H₁₀.

13. The method of claim 9 wherein the reducing gas comprises CO.

14. The method of claim 8 wherein the isotropically etching step further comprises:
providing Cl₂ and CH₄ at a flow ratio Cl₂:CH₄ in a range from 1:40 to 150:1;
applying a substrate bias power of not greater than about 20 W;
maintaining the substrate at a temperature of not less than about 200 degrees Celsius; and
maintaining a gas pressure In the process chamber in a range from 2 to 100 mTorr.

15. The method of claim 14 wherein the isotropically etching step further comprises:
providing CO at flow ratios Cl₂:CO and CH₄:CO ranging from 1:60 to 60:1 and 1:160 to 40:1, respectively.

16. The method of claim 15 wherein the isotropically etching step further comprises:
providing Cl₂, CH₄, and CO at flow ratios Cl₂:CH₄, Cl₂:CO, and CH₄:CO of about 2:1, 1:1, and 1:2.

17. The method of claim 16 wherein the isotropically etching step further comprises:
providing 20 sccm of Cl₂, 10 sccm of CH₄, 20 sccm of CO, and 40 sccm of Ar;
applying 300 W of plasma power and 20 W of bias power,
maintaining the substrate at 350 degrees Celsius; and
maintaining a gas pressure at 4 mTorr.

18. A computer-readable medium containing software that when executed by a computer causes a semiconductor wafer processing system to fabricate a gate structure of a field effect transistor using a method comprising:
supplying a substrate comprising a gate dielectric layer and a gate electrode layer, where the gate dielectric layer is fabricated of a material having a dielectric constant greater than 4.0;
forming a gate electrode above a channel region and portions of source and drain regions of the transistor; and
isotropically etching the gate dielectric layer to notch the gate dielectric layer beneath the gate electrode using a plasma formed from a halogen containing gas and a hydrocarbon gas.

19. The computer-readable medium of claim 18 wherein the forming step further comprises isotropically etching the gate electrode to notch the gate electrode above the gate dielectric layer.

20. The computer-readable medium of claim 18 wherein the gate dielectric layer comprises at least one of HfO₂, HfSiO₂, HfSiON, Al₂O₃, ZrO₂, barium strontium titanate (BST), lead zirconate titanate (PZT), ZrSiO₂, and TaO₂.

21. The computer-readable medium of claim 18 wherein the isotropically etching step further comprises applying a substrate bias power of not greater than about 20 W.

22. The computer-readable medium of claim 18 wherein the isotropically etching step further comprises maintaining the substrate at the temperature of not less than about 200 degrees Celsius.

23. A method of fabricating a gate structure of a field effect transistor, comprising:
supplying a substrate a gate dielectric layer and a gate electrode layer, where the gate dielectric layer is fabricated of hafnium dioxide (HfO₂) or hafnium silicate (HfSiO₂);
forming a gate electrode above a channel region and portions of source and drain regions of the transistor; and
isotropically etching the gate dielectric to notch the gate dielectric layer beneath the gate electrode to form a notched gate dielectric beneath the gate electrode using a halogen containing gas and a hydrocarbon gas with a substrate bias power of not greater than about 20 W and a substrate temperature of not less than about 200 degrees Celsius.

24. The method of claim 23 wherein the plasma further comprises a reducing gas.

25. The method of claim 23 wherein the halogen containing gas comprises a chlorine containing gas.

26. The method of claim 23 wherein the chlorine containing gas is Cl₂.

27. The method of claim 23 wherein the hydrocarbon gas comprises at least one of CH₄, C₂H₆, C₃H₈, and C₄H₁₀.

28. The method of claim 23 wherein the reducing gas comprises CO.

29. The method of claim 1 wherein the isotropically etching step further comprising:
forming the gate dielectric layer having a same width as a notched portion of the gate electrode.

30. The method of claim 1 wherein the isotropically etching step further comprising:
forming the gate dielectric layer having a smaller width as a notched portion of the gate electrode.

31. A method of fabricating a gate structure of a transistor, comprising:
supplying a substrate comprising a gate dielectric layer and a gate electrode layer, where the gate dielectric layer is fabricated of a material having a dielectric constant greater than 4.0;
forming a gate electrode above a channel region and portions of source and drain regions of the transistor; and
isotropically etching the gate dielectric layer to notch the gate dielectric layer beneath the gate electrode using a plasma formed from a halogen containing gas and a hydrocarbon gas.

32. The method of claim 31 wherein the gate dielectric layer comprises at least one of HfO₂, HfSiO₂, HfSiON, Al₂O₃, ZrO₂, barium strontium titanate (BST), lead zirconate titanate (PZT). ZrSiO₂, and TaO₂.

33. The method of claim 31 wherein the hydrocarbon gas comprises at least one of CH₄, C₂H₆, C₃H₈, and C₄H₁₀.

34. The method of claim 31 wherein the halogen containing gas comprises a chlorine containing gas plus reducing gas/bias power less than 20 with reducing gas.
